(19) United States
(12) Patent Application Publication
(10) Pub. No.: US 2015/0054017 A1
(43) Pub. Date: Feb. 26, 2015

(54) LED CHIP PACKAGE

(71) Applicant: Prolight Opto Technology Corporation, Taoyuan Hsien (TW)

(72) Inventors: Chen-Lun HSING CHEN, Taoyuan (TW); Chien-Cheng KUO, Taoyuan (TW); Jung-Hao HUNG, Taoyuan (TW); Cheng-Chung LEE, Taoyuan (TW); Ding-Yao LIN, Taoyuan (TW); Meng-Chi LI, Hsinchu (TW); Ping-Chun TSAI, Taoyuan (TW)

(73) Assignee: Prolight Opto Technology Corporation, Taoyuan Hsien (TW)

(21) Appl. No.: 13/971,066

(22) Filed: Aug. 20, 2013

(51) Int. Cl. H01L 33/40; H01L 33/62

(52) U.S. Cl. CPC H01L 33/40; H01L 33/62
USPC 257/99; 438/33

(57) ABSTRACT

An LED chip package having a topographical glass coating on top surface for enhancing heat dissipation is disclosed. A circular wall is optionally built to surround the LED chip for reflecting light beams from the LED chips; the glass coating further extends to cove the inner wall surface of the circular wall. The larger area the glass coating covers, the more heat the package dissipates in a time unit. The LED chip package according to the present invention exhibits higher thermal dissipation and helps to last longer the life of the LED chip package than a traditional one.

### BACKGROUND

1. Technical Field

The present invention relates to an LED package, especially a package having a topographical glass coating which covers topographically the LED chip and substrate for heat dissipation.

2. Description of Related Art

FIG. 1 is a prior art

FIG. 1 shows a prior art, it discloses a traditional LED package which has an LED chip 11 mounted on a central copper nugget 10. A left copper nugget 101 is configured in the right of the central copper nugget 10. A right copper nugget 102 is configured in the right of the central copper nugget 10. Molding compound 14 is filled the gaps between the three copper nuggets 101, 10, 102 for electric insulation and fixation between the copper nuggets. The LED chip 11 has a first top electrode electrically coupled to the left copper nugget 101 through a bonding wire 121. The LED chip 11 has a second top electrode electrically coupled to the right copper nugget 102 through a bonding wire 122. It is well-known that heat accumulation shortens the life of LED, and hence the LED life can last longer if the heat generated from the LED chip 11 can be removed more effectively.

### BRIEF DESCRIPTION OF THE DRAWINGS

FIG. 1 is a prior art

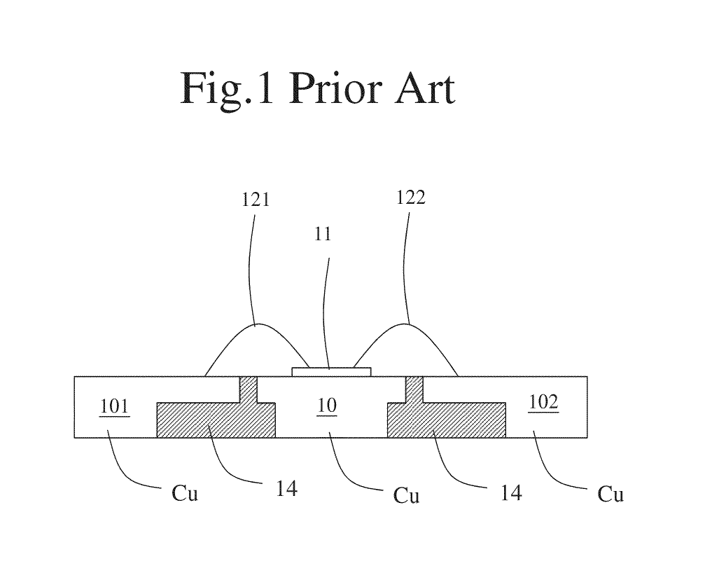

FIG. 2 is a first embodiment according to the present invention

FIG. 3A˜3B is a second embodiment according to the present invention

FIG. 4 is a third embodiment according to the present invention

FIG. 5 is a fourth embodiment according to the present invention

FIG. 6 is a fifth embodiment according to the present invention

FIG. 7 is a sixth embodiment according to the present invention

FIG. 8 is a seventh embodiment according to the present invention

FIG. 9 is an eighth embodiment according to the present invention

FIG. 10 is a ninth embodiment according to the present invention

FIG. 11 is a tenth embodiment according to the present invention

FIG. 12 is an eleventh embodiment according to the present invention

FIG. 13 is a first process for producing a topographically glass-coated chip

FIG. 14A˜14B is a drawing of the process described in FIG. 13

FIG. 15 is a second process for producing a topographically glass-coated chip according to the present invention

FIG. 16A˜16B is a drawing of the process described in FIG. 15

FIG. 17 is an experiment data according to the presentation

FIG. 18 is a drawing expression for the experiment data of FIG. 17

### DETAILED DESCRIPTION OF THE INVENTION

Air has a thermal conductivity of 0.024 W/mK, and glass has a thermal conductivity 0.8 W/mK which is some 33 times that of the air. Therefore a better heat transmission is displayed for a glass film than that of the air. This invention suggests applying a topographical glass coating on the top surface of the LED chip for a better heat dissipation. The topographical glass coating of this invention is made over the LED chip, and the topographical glass coating can even extends to peripheral area on the surface of the base substrate where the LED chip is mounted to even faster transmit the heat from the LED chip into the air. The larger area the glass coating covers, the more heat the package dissipates in a time unit. The glass coating in the present invention has a thickness less than 20 nm that is quite a thin film in comparison with the thickness of an LED chip which has a thickness of 50˜250 um.

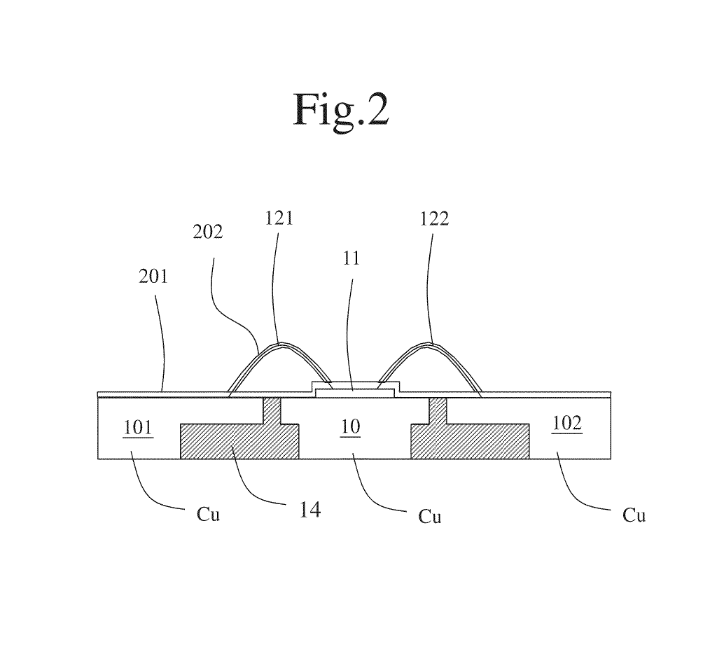

FIG. 2 is a first embodiment according to the present invention

FIG. 2 shows that an LED chip package has an LED chip 11 mounted on a top of a central copper nugget 10. A first top electrode and a second top electrode is configured on the top surface of the LED chip 11. A left copper nugget 101 is configured on the left of the central copper nugget 10. A second copper nugget 102 is configured on the right of the central copper nugget 10. A first metal wire 121 electrically couples the first top electrode to the left copper nugget 101, and a second metal wire 122 electrically couples the second top electrode to the right copper nugget 102. A topographical glass coating 201 covers the surface of the bonding wires 121, 122, the top surface of the LED chip 11, and the exposed top surface of the copper nuggets 101, 10, 102. A topographical glass coating 202 wraps the wires 121, 122.

The material can be used for the topographical glass coating 201 is a material selected from the group consisting of silicon oxide (SiOx) where x=1.5˜2, silicon nitride (SiNx), aluminum oxide (AlOx), aluminum oxynitride (AlOxNy), and silica carbon nitride (SiCxNy). A traditional sputter process can be performed to produce the coating of Aluminum compound, and usually a traditional Plasma-Enhanced Chemical Vapor Deposition (PECVD) process can be used to produce the coating of Silicon compound.

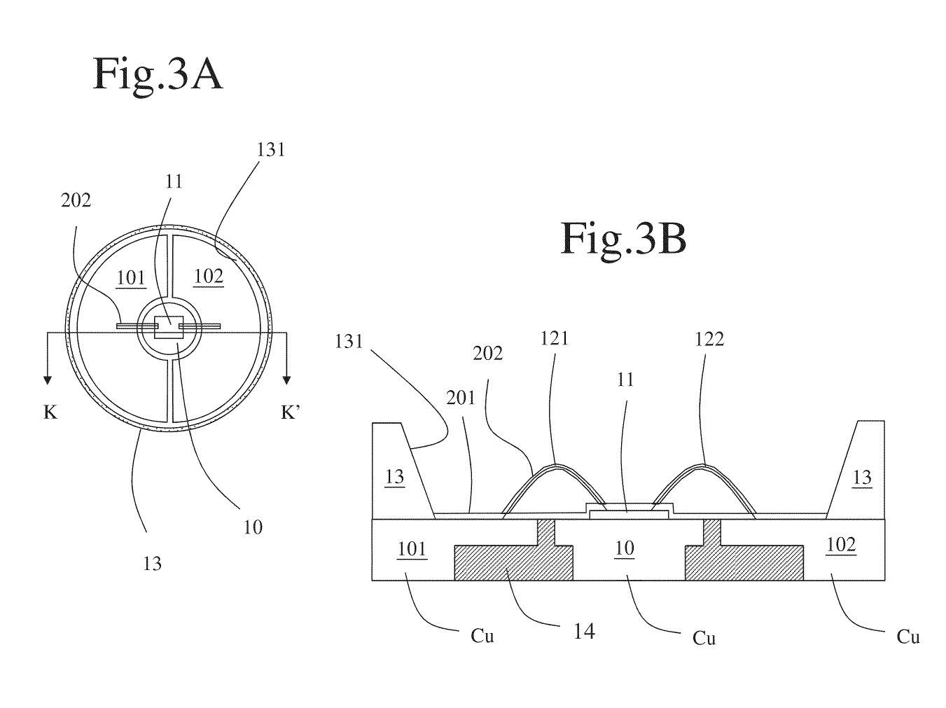

FIG. 3A˜3B is a second embodiment according to the present invention

FIG. 3A shows that an LED chip package with a circular reflecting wall 13 is configured so as to reflect the light beams from the LED chip 11 forward. The circular wall 13 surrounds the LED chip 11 and the glass-coated bonding wires 202. The circular wall 13 has an inner wall surface 131 for reflecting the light beams from the LED chip 11. The topographical glass coating 201 covers the top surface of the LED chip 11 and the top surface of the area surrounded by the circular wall 13; that is to say, the topographical glass coating 201 covers the top surface of the LED chip 10 and the exposed top surface of the copper nuggets 101, 10, 102.

FIG. 3B is a section view according to line KK′ of FIG. 3A.

FIG. 3B shows that an LED chip 11 is mounted on the top surface of the central copper nugget 10. The topographical glass coating 201 covers the top surface of the area surrounded by the circular wall 13. A topographical glass coating 202 wraps the wires 121, 122.

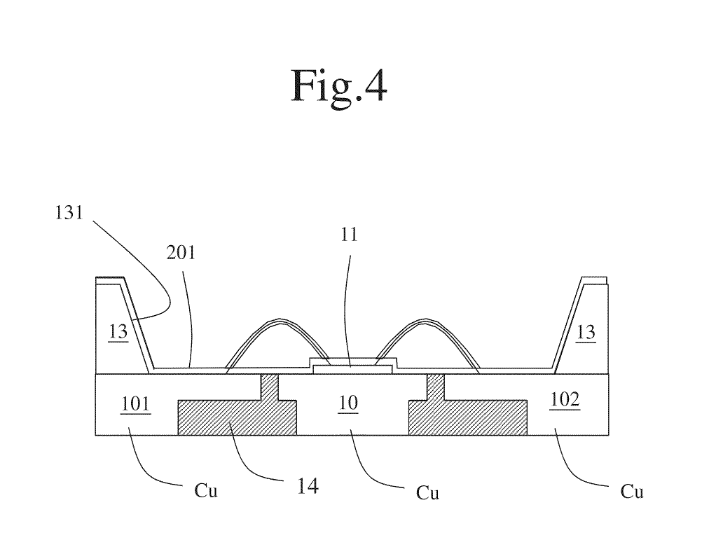

FIG. 4 is a third embodiment according to the present invention

FIG. 4 shows that an LED chip package surrounded by the circular wall 13. Except for the area surrounded by the circular wall 13, the topographical glass coating 201 extends to cover the inner wall surface 131 of the circular wall 13. The lager area the glass coating 201 covers, the more heat the package dissipates in a time unit.

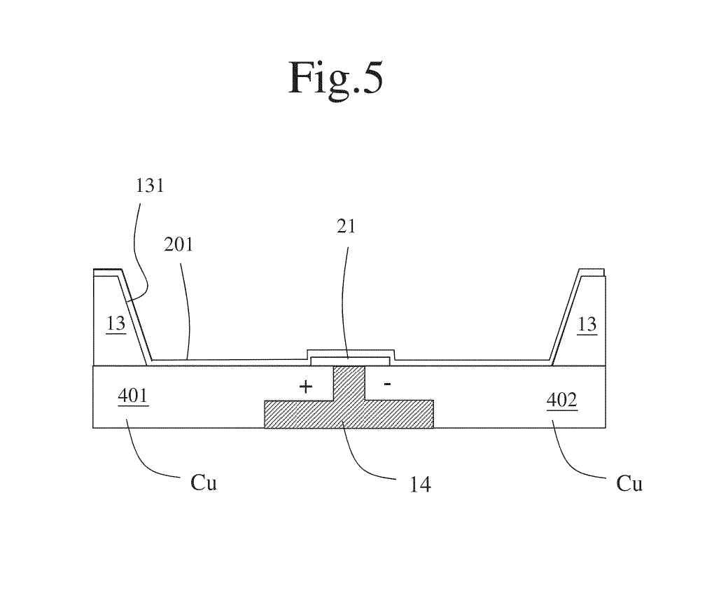

FIG. 5 is a fourth embodiment according to the present invention

FIG. 5 shows that a left copper nugget 401 and a right copper nugget 402, a insulating molding compound 14 is configured between the two copper nuggets 401, 402. The top surface of the left copper nugget 401 is configured coplanar with the top surface of the right copper nugget 402. An LED chip 21 is flip-chip mounted on the two nuggets 401, 402. In other words, the LED chip 21 having a first bottom electrode and a second bottom electrode straddles over the left copper nugget 401 and the right copper nugget 402. The first bottom electrode of the LED chip 21 electrically couples to the left copper nugget 401, and the second bottom electrode of the LED chip 21 electrically couples to the right copper nugget 402. A topographical glass coating 201 covers the top surface of the LED chip 21 and the exposed top surface of the copper nuggets 401, 402. A circular wall 13 is optionally built to surround the LED chip 21; and the topographical glass coating 201 extends to cover the inner wall surface 131 of the circular wall 13.

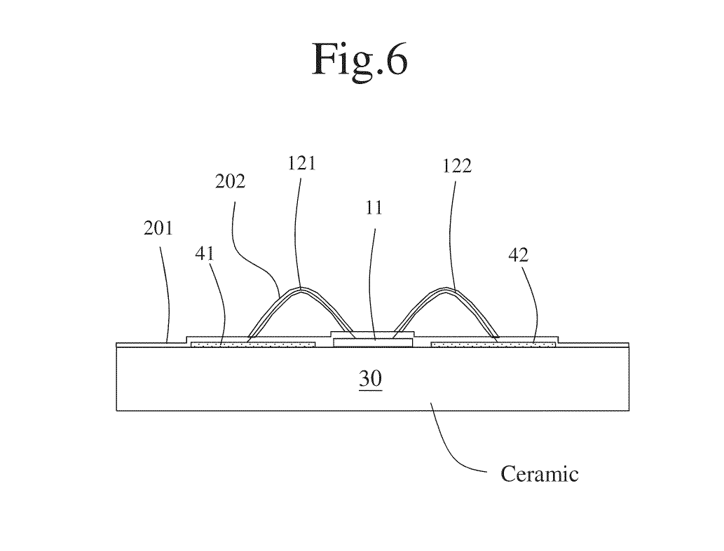

FIG. 6 is a fifth embodiment according to the present invention

FIG. 6 shows that a ceramic substrate 30 is used as the base substrate. A left metal pad 41 is configured on a top surface of the ceramic substrate 30, and a right metal pad 42 is configured on a top surface of the ceramic substrate 30. An LED chip 11 has a first top electrode and a second top electrode. A first metal wire 121 electrically couples the first top electrode to the left copper metal pad 41. A second metal wire 122 electrically couples the second top electrode to the right metal pad 42. A topographical glass coating 201 topographically covers the top surface of the LED chip 11, metal pads 41, 42 and the exposed top surface of the ceramic substrate 30. A topographical glass coating 202 wraps the wires 121, 122.

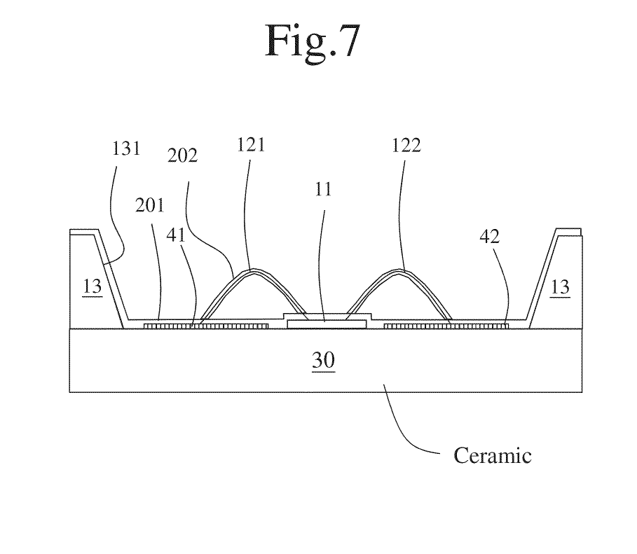

FIG. 7 is a sixth embodiment according to the present invention

FIG. 7 shows an LED chip package which is similar to the one of FIG. 6. The main difference is that a circular wall 13 is built to surround the LED chip for reflecting the light beams from the LED chip 11. The topographical glass coating 201 further extends to cover the inner wall surface 131 of the circular wall 13.

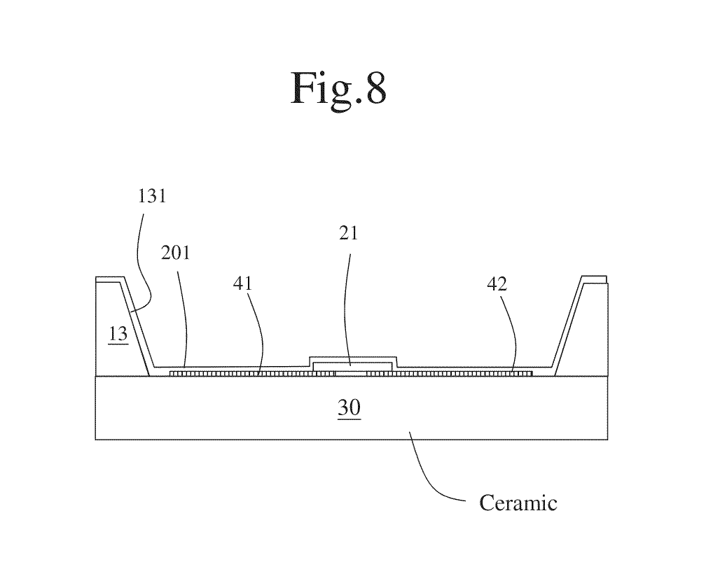

FIG. 8 is a seventh embodiment according to the present invention

FIG. 8 shows that a ceramic substrate 30 is used as a basic substrate for the LED chip package. A left metal pad 41 is configured on a top surface of the ceramic substrate 30. A right metal pad 42 is configured on a top surface of the ceramic substrate 30. An LED chip 21 is flip-chip mounted on the two metal pads 41, 42. That is to say, the LED chip 21 straddles over the first metal pad 41 and the second metal pad 42. A topographical glass coating 201 covers the top surface of the LED chip 21, metal pads 41, 42 and the exposed top surface of the ceramic substrate 30.

A circular wall 13 is optionally built to surrounds the LED chip 21 and the metal pads 41, 42. The topographical glass coating 201 further extends to cover the inner wall surface 131 of the circular wall 13.

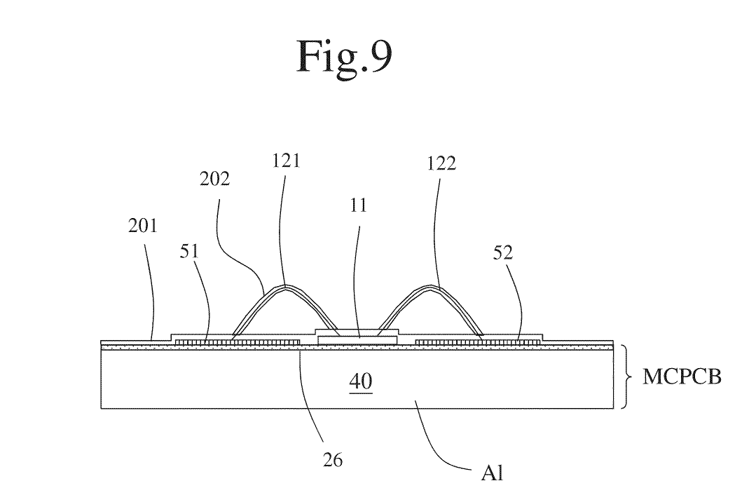

FIG. 9 is an eighth embodiment according to the present invention

FIG. 9 shows that a metal core printed circuit board (MCPCB) is used as the base substrate. A dielectric layer 26 is configured on a top surface of a metal core 40. Aluminum (Al) is used as the metal core 40 for an example. A left metal pad 51 is configured on a top surface of the dielectric layer 26. A right metal pad 52 is configured on a top surface of the dielectric layer 26. An LED chip 21 has a first top electrode and a second top electrode. A first metal wire 121 electrically couples the first top electrode to the left metal pad 51. A second metal wire 122 electrically couples the second top electrode to the right metal pad 52. A topographical glass coating 201 covers the surface of the bonding wires 212, 122, the top surface of the LED chip 11, and the exposed top surface of the dielectric layer 26. A topographical glass coating 202 wraps the wires 121, 122.

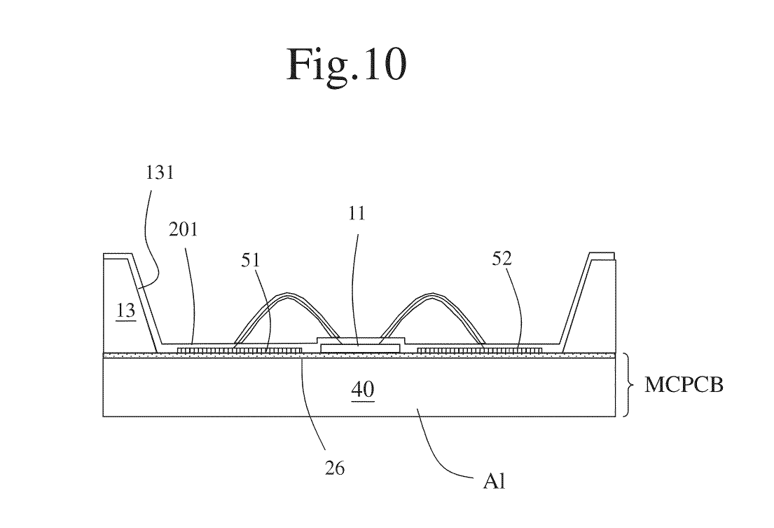

FIG. 10 is a ninth embodiment according to the present invention

FIG. 10 shows an LED chip package which is similar to the one of FIG. 9. The main difference is that a circular wall 13 is optionally built to surround the LED chip for reflecting the light beams from the LED chip 11. The topographical glass coating 201 further extends to cover the inner wall surface 131 of the circular wall 13.

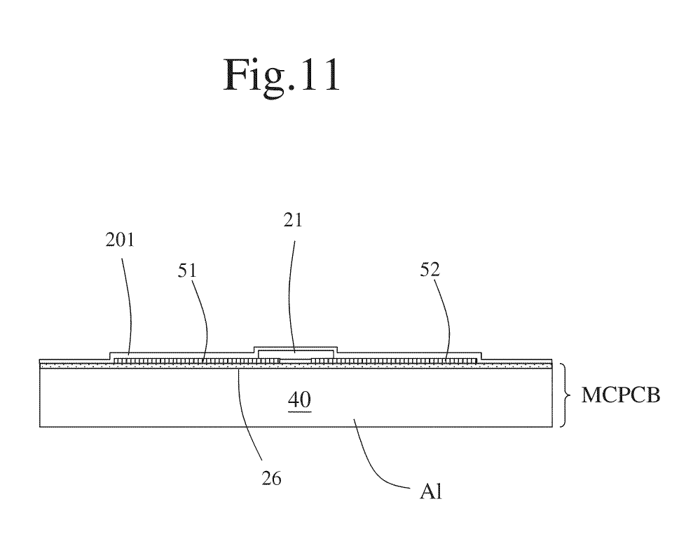

FIG. 11 is a tenth embodiment according to the present invention

FIG. 11 shows that an LED chip is flip-chip mounted on a metal core printed circuit board (MCPCB) substrate. The MCPCB substrate has a metal core 40, Aluminum (Al) is used as an example, and a dielectric layer 26 configured on a top surface of the metal core 40. A left metal pad 51 is configured on a top surface of the dielectric layer 26. A right metal pad 52 is configured on a top surface of the dielectric layer 26. An LED chip 21 is flip-chip mounted on the two metal pads 51, 52. That is to say, the LED chip 21 straddles over the left metal pad 51 and the right metal pad 52. A topographical glass coating 201 covers the top surface of the LED chip 21, metal pads 51, 52 and the exposed top surface of the dielectric layer 26.

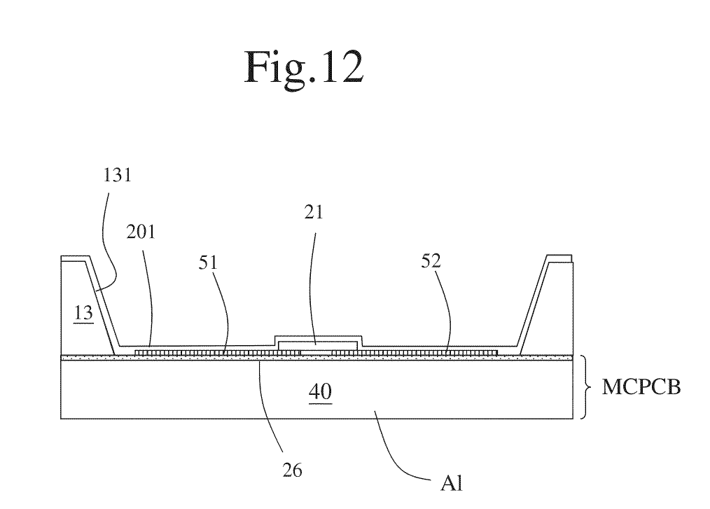

FIG. 12 is an eleventh embodiment according to the present invention

FIG. 12 shows that a circular wall 13 is optionally built to surround the LED chip 21 and the metal pads 51, 52. The topographical glass coating 201 further extends to cover the inner wall surface 131 of the circular wall 13.

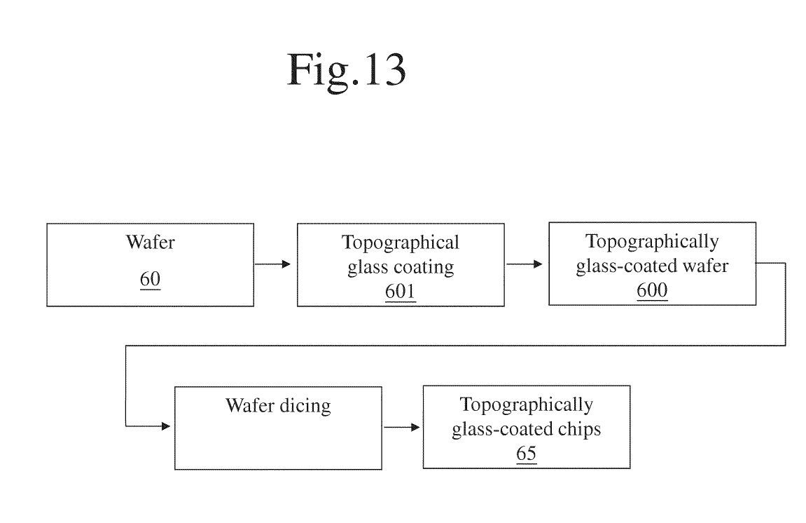

FIG. 13 is a first process for producing a topographically glass-coated chip according to the present invention

FIG. 13 shows that the process to produce glass-coated chips comprises:

preparing a wafer 60;

performing topographical glass coating 601 on the top surface of the wafer 60;

producing topographically glass-coated wafer 600;

performing wafer dicing; and

producing topographically glass-coated chips 65.

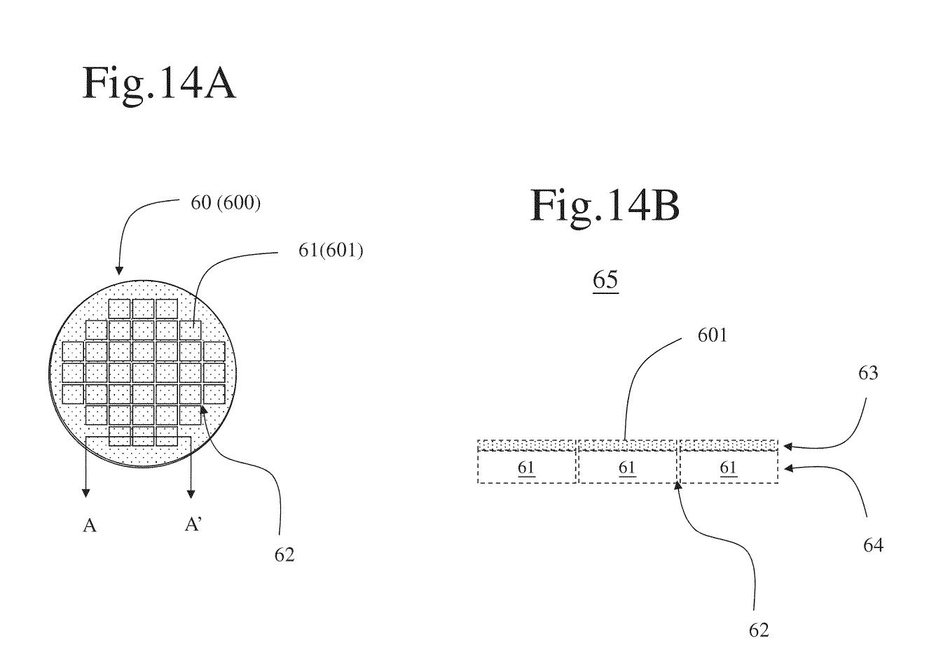

FIG. 14A˜14B is a drawing of the process described in FIG. 13

FIG. 14A shows that a wafer 60 is prepared and a plurality of chips 61 is made on the wafer 60. A topographical glass coating 601 is applied over the top surface of the wafer 60 to produce a glass-coated wafer 600.

FIG. 14B shows a section view according to line AA′ of FIG. 14A

FIG. 14B shows that a glass coating 601 is applied on a top surface of each chip 61. The topographical glass coating 601 has a vertical edge 63 flushed with a vertical edge 64 of the chip 61. The topographically glass-coated wafer 600 is then sawn according to the dicing line 62 to produce a plurality of topographically glass-coated chips 65.

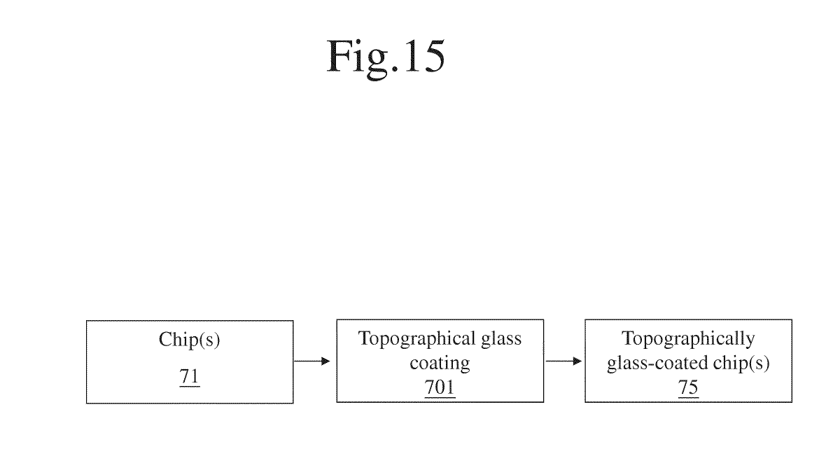

FIG. 15 is a second process for producing a topographically glass-coated chip according to the present invention

FIG. 15 shows that the process to produce glass-coated chips comprises:

preparing chips 71 on a dicing tap 70;

performing a topographical glass coating 701 over the chips; and

producing a plurality of glass-coated chips 75.

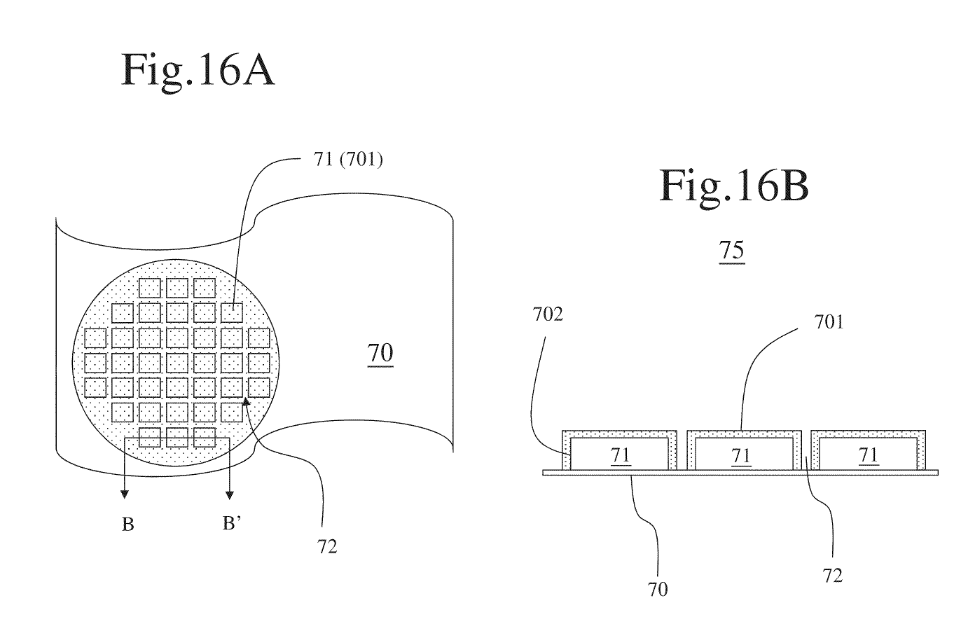

FIG. 16A˜16B is a drawing of the process described in FIG. 15

FIG. 16A shows a plurality of chips 71 is configured on a top surface of a dicing tape 70. Since the chips 71 are collected after sorting from a diced wafer. A space 72 exists between neighboring chips 71 on the dicing tape 70. A topographical glass coating 701 is then applied on the top surface of the chips 71 to cover the top surface of the chip 71; in addition, the four vertical sides 702 of the chip 71 is also covered by the glass coating 701 topographically.

FIG. 16B shows a section view according to line BB′ of FIG. 16A

FIG. 16B shows that a glass coating 701 is applied on a top surface of each chip 71. In the meanwhile, the sorted chips 71 configured on the dicing tape 70 are independent from one another. Therefore, the four vertical sides 702 are also covered by the glass coating 701.

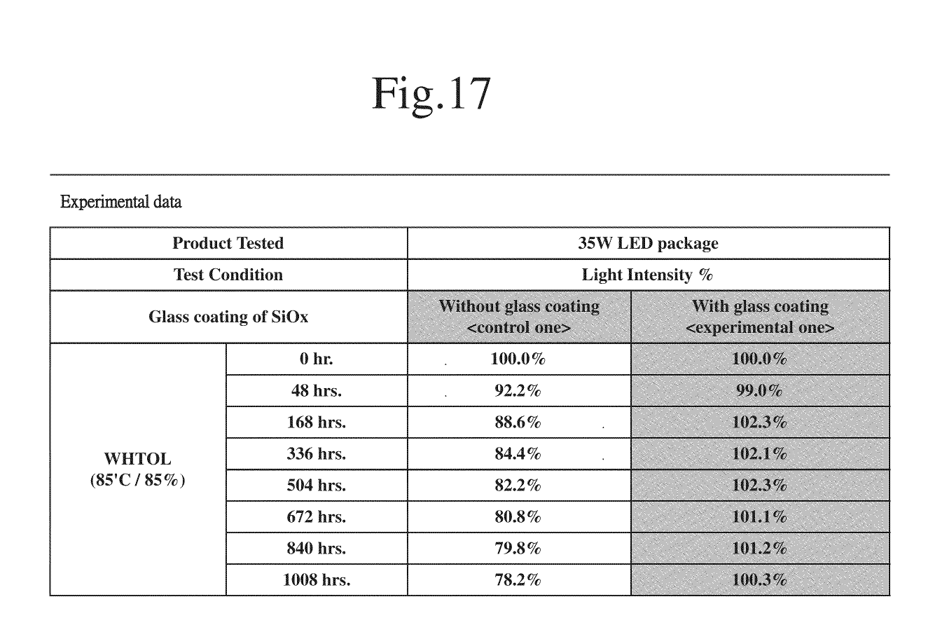

FIG. 17 is an experiment data of a reliability test according to the present invention

FIG. 17 shows that a Wet and High-Temperature Operation Life (WHTOL) test is performed over the product of FIG. 9 with/without glass coating on the top surface of the product. The product of FIG. 9 which has a glass coating of SiOx is an Experimental One, and the other one without having a glass coating of SiOx is a Control One. The data shows a 35 W LED package is tested under 85 degrees Celsius, and 85% relative humidity. The relative light intensity shows that the experimental one keeps 100.3% light intensity after 1,008 hours test; and the control one degrades as time elapsing, and only 78.2% light intensity is left after 1,008 hours test.

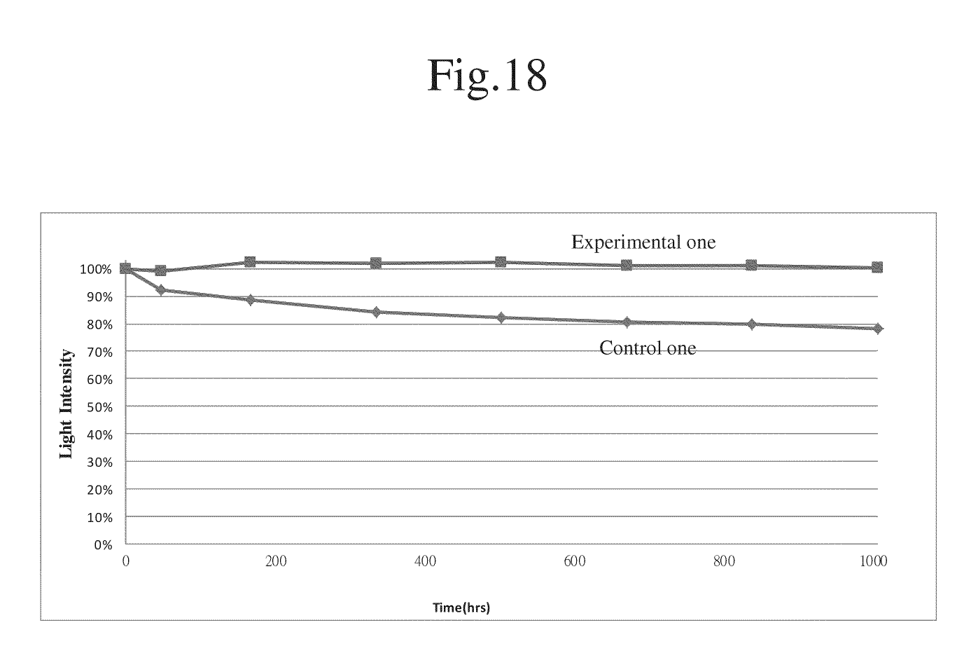

FIG. 18 is a drawing expression for the experiment data of FIG. 17

FIG. 18 shows that the Light Intensity is in the Y-coordinate and Test Hours is in the X-coordinate. The upper line, experimental one, keeps light intensity almost unchanged or 100.3% light intensity remains in the end of 1,008 hours test. However, the lower line, control one, degrades gradually as time elapsing, only 78.2% light intensity is left in the end of 1,008 hours test. Apparently, the present invention with topographical glass coating over the surface of the LED chip package has caused a great improvement in the heat dissipation of the product.

While several embodiments have been described by way of example, it will be apparent to those skilled in the art that various modifications may be configured without departing from the spirit of the present invention. Such modifications are all within the scope of the present invention, as defined by the appended claims.

What is claimed is:

1. An LED chip package, comprising:
an LED chip; has a first top electrode and a second top electrode;
a middle copper nugget, carrying the LED chip;
a left copper nugget;
a right copper nugget;
a first metal wire, electrically coupling the first top electrode to the left copper nugget;
a second metal wire, electrically coupling the second top electrode to the right copper nugget; and
a topographical glass coating, covering the surface of the bonding wires, the top surface of the LED chip, and the exposed top surface of the copper nuggets.

2. The LED chip package as claimed in claim 1, further comprising:
a circular wall, surrounding the LED chip and the bonding wires; wherein the topographical glass coating, covering the top surface of an area surrounded by the circular wall.

3. The LED chip package as claimed in claim 2, wherein the topographical glass coating, further extending to cover the inner wall surface of the circular wall.

4. An LED chip package, comprising:
a left copper nugget;
a right copper nugget;
an LED chip, having a first bottom electrode and a second bottom electrode; straddles over the left copper nugget and the right copper nugget; wherein the first bottom electrode electrically coupled to the left copper nugget, and the second bottom electrode electrically coupled to the right copper nugget, and
a topographical glass coating, covering the top surface of the LED chip and the exposed top surface of the copper nuggets.

5. The LED chip package as claimed in claim 4, further comprising:
a circular wall, surrounding the LED chip; and
the topographical glass coating further extending to cover the inner wall surface of the circular wall.

6. The LED chip package as claimed in claim 1, wherein the topographical glass coating containing a material selected from the group consisting of silicon oxide, silicon nitride, aluminum oxide, aluminum oxynitride, and silica carbon nitride.

7. An LED chip package, comprising:
a ceramic substrate;
a left metal pad, configured on a top surface of the ceramic substrate;
a right metal pad; configured on a top surface of the ceramic substrate;
an LED chip, having a first top electrode and a second top electrode;
a first metal wire, electrically coupling the first top electrode to the left copper metal pad 41; and
a second metal wire, electrically coupling the second top electrode to the right metal pad.
a topographical glass coating, covering the top surface of the LED chip, metal pads, and the exposed top surface of the ceramic substrate.

8. The LED chip package as claimed in claim 7, further comprising:
a circular wall, surrounding the LED chip and the bonding wires; and
the topographical glass coating further extending to cover the inner wall surface of the circular wall.

9. The LED chip package as claimed in claim 7, wherein the topographical glass coating containing a material selected from the group consisting of silicon oxide, silicon nitride, aluminum oxide, aluminum oxynitride, and silica carbon nitride.

10. An LED chip package, comprising:
a ceramic substrate 30;
a left metal pad, configured on a top surface of the ceramic substrate;
a right metal pad; configured on a top surface of the ceramic substrate;
an LED chip, straddles over the left metal pad and the right metal pad;
a topographical glass coating, covering the top surface of the LED chip, metal pads and the exposed top surface of the ceramic substrate.

11. The LED chip package as claimed in claim 10, further comprising:
a circular wall, surrounding the LED chip and the metal pads; and
the topographical glass coating further extending to cover the inner wall surface of the circular wall.

12. The LED chip package as claimed in claim 10, wherein the topographical glass coating containing a material selected from the group consisting of silicon oxide, silicon nitride, aluminum oxide, aluminum oxynitride, and silica carbon nitride.

13. An LED chip package, comprising:
a MCPCB substrate, having a metal core and a dielectric layer configured on a top surface of the metal core;
a left metal pad, configured on a top surface of the dielectric layer;
a right metal pad; configured on a top surface of the dielectric layer;
an LED chip, having a first top electrode and a second top electrode;
a first metal wire, electrically coupling the first top electrode to the left metal pad; and
a second metal wire, electrically coupling the second top electrode to the right metal pad; and
a topographical glass coating, covering the bonding wires, the top surface of the LED chip, and the exposed top surface of the dielectric layer.

14. The LED chip package as claimed in claim 13, further comprising:
a circular wall, surrounding the LED chip and the metal pads; and
the topographical glass coating further extending to cover the inner wall surface of the circular wall.

15. The LED chip package as claimed in claim 13, wherein the topographical glass coating containing a material selected from the group consisting of silicon oxide, silicon nitride, aluminum oxide, aluminum oxynitride, and silica carbon nitride.

16. An LED chip package, comprising:
a MCPCB substrate, having a metal core, and a dielectric layer on a top surface of the metal core;
a left metal pad, configured on a top surface of the dielectric layer;
a right metal pad; configured on a top surface of the dielectric layer;
an LED chip, straddles over the left metal pad and the right metal pad; and
a topographical glass coating, covering the top surface of the LED chip, metal pads and the exposed top surface of the dielectric layer.

17. The LED chip package as claimed in claim 16, further comprising:
a circular wall, surrounding the LED chip and the metal pads; and
the topographical glass coating further extending to cover the inner wall surface of the circular wall.

18. The LED chip package as claimed in claim 16, wherein the topographical glass coating containing a material selected from the group consisting of silicon oxide, silicon nitride, aluminum oxide, aluminum oxynitride, and silica carbon nitride.

19. A wafer with a topographical glass coating on top surface, comprising:
a wafer; and
a topographical glass coating, covering the top surface of the wafer.

20. The wafer as claimed in claim 19, wherein the topographical glass coating containing a material selected from the group consisting of silicon oxide, silicon nitride, aluminum oxide, aluminum oxynitride, and silica carbon nitride.

21. A chip with a topographical glass coating on top surface, comprising:
a chip; and
a topographical glass coating, covering the top surface of the chip; wherein the topographical glass coating has a vertical edge flushed with a vertical edge of the chip.

22. The chip with a topographical glass coating on top surface as claimed in claim 21, wherein the topographical glass coating containing a material selected from the group consisting of silicon oxide, silicon nitride, aluminum oxide, aluminum oxynitride, and silica carbon nitride.

23. A process for preparing a topographically glass-coated chip, comprising:
preparing a wafer; and
performing a topographical glass coating over the wafer.

24. A process for preparing a topographically glass-coated chip as claimed in claim 23, further comprising:
dicing the wafer to yield a plurality of chips with a topographical glass coating on top surface.

25. The topographically glass-coated chip prepared according to claim 24, wherein
the topographical glass coating, having four vertical sides; and
the chip, having four vertical sides; wherein
each vertical side of the topographical glass coating is flushed with a corresponding vertical side of the chip.

26. A process for preparing a topographically glass-coated chip, comprising:
preparing a chip on a dicing tap; and
performing a topographical glass coating over the chip.

27. The topographically glass-coated chip prepared according to claim 26, wherein the topographical glass coating, covering both the top surface of the chip and the four vertical side.
